(19) United States
(12) Patent Application Publication
(10) Pub. No.: US 2024/0276882 A1
(43) Pub. Date: Aug. 15, 2024

(54) Multistage Thermoelectric Cooler with Phononic Structure

(71) Applicant: William N. Carr, Gainesville, FL (US)

(72) Inventor: William N. Carr, Gainesville, FL (US)

(21) Appl. No.: 18/110,182

(22) Filed: Feb. 15, 2023

(51) Int. Cl. H10N 19/00; F25B 21/02

(52) U.S. Cl. CPC H10N 19/101; F25B 21/02; H01L 23/38

(57) ABSTRACT

A multi-stage thermoelectric cooler is processed from semiconductor starting wafers. Efficiency for cooling is enhanced with semiconductor phononic nanowires increasing the ratio of electrical conductivity to thermal conductivity within a Peltier thermoelectric device. In embodiments, the phononic structure comprises phononic crystal. Applications include micro-refrigerators for cooling photonic detectors in applications such as focal plane array (FPA) imagers and semiconductor diode detectors. Other applications for the micro-refrigerator includes providing a cooled platform for a media of interest, including chemicals, a chemical reaction, and a variety of semiconductor devices.

### FIELD OF THE INVENTION

This invention relates to a thermoelectric device comprising semiconductor phononic structure.

### BACKGROUND OF THE INVENTION

A cascade of cooled substrates comprising a multistage thermoelectric cooling device can be structured to provide a heat pump. A multistage thermoelectric cooling device is also known as a micro-refrigerator. A Peltier thermocouple junction is disposed on each cooled platform of the device. The plurality of cooled substrates are electrically- and thermally-connected in cascade. Each cooled substrate within the cascade comprises a Peltier thermoelectric couple. The Peltier couple disposed on each cooled platform is powered through semiconductor nanowires suspended from and thermally-connected to a higher temperature substrate.

The junction couple on each cooled substrate is an ohmic connection between p-type and an n-type semiconductor nanowires of the thermocouple, with nanowires anchored on a substrate maintained at a higher temperature. The anchored connection includes a voltage source which powers each single stage of the thermoelectric cooling device. The cooled substrate is suspended by the nanowires from the warmer junction coupling to the higher temperature substrate with its voltage source. The higher temperature substrate may comprise a surrounding heatsink platform or another cooled substrate within the cascade of Peltier cooling thermocouples.

A larger structure comprising a plurality of the multistage thermoelectric coolers, each thermally-connected to a larger substrate, may be an attached platform cooled to the minimum temperature of the thermoelectric cascade. This larger structure may provide a cooled environment for such as a photonic imager, a low noise integrated circuit, or simply a cooled storage environment for a material of interest. The micro-refrigerator is typically structured with dimensions comparable to or less than said larger cooled substrate.

The semiconductor nanowires may be decorated with phononic structural elements that significantly restrict the flow of heat from the hot junction to the cold junction, thereby increasing the thermal isolation of the cold junction and increasing efficiency for Peltier thermoelectric cooling. These phononic elements involve scattering mechanisms in nanowires that restrict transport of thermal energy.

Structural elements within the nanowires are separated by a distance less than the mean free path of at least some of heat conducting phonons moving in the vector direction of thermal flow. These phononic elements may comprise phononic crystal (PnC) comprised of an orderly arrangement of structural elements having a type of phononic resonance provided by a phononic bandgap, or a random arrangement of structural elements providing a non-resonant scattering. In all cases the phononic structure provides a reduction of phonon transport along the length of the thermally-isolating nanowires.

Semiconductor Peltier thermoelectric coolers are more efficient when formed of certain semiconductors having a high Seebeck coefficient, high electrical conductivity, and low thermal conductivity. Semiconductors such as Bi₂Te₃ providing a high thermoelectric power factor over a wide temperature range find widespread application in Peltier coolers for specific applications. In the past, more common semiconductors such as silicon and germanium have been limited in application for thermoelectric coolers because of their intrinsic higher thermal conductivity.

Phononic structuring of semiconductor thin films has been shown to be very effective in providing significant reduction of thermal conductivity of these thin films to ultra-low levels, thereby opening new application areas for thermoelectric cooling devices manufactured in semiconductor foundries. For example, J. Nakagawa et al disclose the significant decrease in thermal conductivity of phononically-structured silicon thin films in a publication “Crystal structure-dependent thermal conductivity in two-dimensional phononic crystal nanostructures”, Appl. Phys. Lett. Vol. 107, 023105, 2015.

Thin films of semiconductor may be physically patterned with decorations to create a phononic crystal (PnC) in a silicon thin film structured with a phononic bandgap (e.g. S. Mohammadi et al, Appl. Phys. Lett., vol. 92, 221905 (2008). Phononic crystal bandgaps define phonon transport acoustic frequency bands wherein the propagation of heat-conduction phonons is forbidden. Phonon scattering within a PnC-structured nanowire is obtained by physically configuring the nanowire to reduce the phononic Brillouin zone, and in some embodiments include a plurality of arrayed layers or interfaces.

An infrared sensor device wherein embodiments include a single-stage Peltier thermoelectric cooler is disclosed in W. Carr, “Platform comprising an infrared sensor”, U.S. Pat. No. 9,006,857 issued Apr. 14, 2015. A thermally-isolated cooled platform is disclosed that comprises a single stage thermoelectric cooler, the cooled substrate suspended from a surrounding substrate by phononic nanowires.

Another micro-refrigerator based on a single-stage Peltier cooler with semiconductor phononic nanowires is disclosed in W. Carr, “Thermoelectric micro-platform for cooling and temperature sensing”, U.S. Pat. No. 9,236,552 issued Jan. 12, 2016.

A more complex semiconductor device comprising a single-stage Peltier thermoelectric (PTE) cooler is disclosed in W. Carr, “Phononically-enhanced imager (PEI) pixel” U.S. Pat. No. 11,381,761 issued Jul. 5, 2022.

Prior art listed above does not disclose a multi-stage Peltier thermoelectric cooler wherein the cooling efficiency is significantly enhanced with phononic structure disposed within nanowires. Multi-stage thermoelectric coolers comprise two or more cooled substrates in cascade, each with a Peltier cooling element, and wherein cooled substrates are connected thermally in series. In a multi-stage Peltier thermoelectric cooler, each successive substrate within a thermal cascade is thermoelectrically cooled to a lower temperature.

Desirable improvements needed to advance state of the art for thermoelectric coolers include an increase of Peltier cooling efficiency, reduced weight, volume, cost, material robustness, and compatibility with existing semiconductor foundries. An important application area is to integrate a multi-stage thermoelectric cooler to provide a low temperature environment for photonic imagers, low noise integrated circuits, and various sensors wherein performance is significantly enhanced by the low temperature environment.

### SUMMARY OF THE INVENTION

An object of this invention is to provide a multistage thermoelectric cooler with phononic structure (TCPS) comprised of a plurality of cooled substrates, wherein each cooled substrate comprises one or more of a Peltier thermoelectric couple. The final cooled substrate in the cascade of thermally-connected substrates is cooled to the lowest temperature of the cascade. In some embodiments, a plurality of the multi-stage thermoelectric coolers are thermally connected to cool a much larger substrate such as a semiconductor imager with dimensions of over 1 cm on a side. The multi-stage thermoelectric cooler of this invention has dimensions comparable to many existing semiconductor integrated circuits and can cool these circuits within a single package.

In this invention the thermoelectric devices are comprised of substrates having a cold junction and supported by phononic nanowires having reduced thermal conductivity. An important aspect involved in embodiments of the present invention is to provide a reduced thermal conductivity through the length of phononically-structured nanowires. In the present invention, physical decorations along the length of nanowires reduce the transport flow of heat conducting phonons thereby reducing thermal conductivity.

This invention comprises a multi-stage thermoelectric cooler with phononic structure (TCPS) wherein each stage comprises a cooled substrate and supporting nanowires. Each cooled substrate comprises at least one Peltier thermocouple thermally- and electrically-connected with another substrate at a higher temperature.
one or more first cooled substrates are at least partially suspended from a heatsink substrate and receive power from the heatsink substrate through phononic nanowires;
one or more additional cooled substrates are each at least partially suspended from and powered from a cooled substrate maintained at a higher temperature, wherein the one or more additional cooled substrates each receive power from said substrate maintained at a higher temperature;
the phononic nanowires comprise a phononic layer structured with nonresonant and/or resonant elements providing a reduced thermal conductivity for each phononic nanowire;
the phononic layer increases the ratio of electrical conductivity to thermal conductivity along the length of each phononic nanowire, and
   the cooled substrates are connected in a thermal cascade wherein each cooled substrate is maintained at a temperature lower than the substrate supplying power, thereby providing a TCPS wherein the final cooled substrate in the cascade is maintained at a minimum temperature.

The second cooled substrate is suspended by phononic nanowires from one or more first cooled substrates, and the first cooled substrates provide power to one or more Peltier thermocouples with the cooled junction couople disposed in the second cooled substrate.

In embodiments, some ancillary nanowires are physically connected to a cooled platform to provide a mechanically rigid support, or static stress to position or orient said cooled platform without supplying power to said platform.

In embodiments, the TCPS may comprise a cascade of electrically-connected and thermally-connected substrates, each platform cooled to a successively lower temperature within the cascade.

A cooled substrate in an embodiment may comprise, or be thermally-connected to, a discrete photonic detector or array of detectors including, without limitation, a thermopile, photodiode, superlattice detector, thermistor bolometer, or pyroelectric sensor.

The TCPS in an embodiment may comprise a CMOS readout integrated circuit (ROIC) disposed in or on a cooled substrate or in the surrounding heatsink substrate.

The TCPS in an embodiment may be adapted, wherein some phononic nanowires are positioned to provide an ohmic circuit connection between circuit elements disposed on substrates that do not comprise Peltier cooling elements.

A cooled platform of the TCPS in embodiments, provides a refrigerated environment for short and long term storage of a media of interest, the media of interest comprising without limitation, a chemical material, reacting chemical, or a semiconductor device.

The phononic layer of nanowires comprises a crystalline or polycrystalline semiconductor wherein structural elements within the phononic layer are physically separated by less than the mean-free-path (mfp) of at least some heat conducting phonons.

The phononic layer comprises one or more of a semiconductor material selected from the group, without limitation, silicon, silicon germanium, silicon carbide, gallium nitride, an organic semiconductor, compounds of antimony, bismuth, cobalt, lanthanum, lead, selenium, sulfur, tellurium and semiconductor superlattice structures.

In an embodiment, the phononic layer of a nanowire comprises phononic crystal (PnC) having a phononic bandgap, wherein structural sites are arranged in an orderly fashion, and the phononic crystal reduces thermal transport of phonons.

In an embodiment, the phononic layer of at least some phononic nanowires includes nonresonant scattering structure having phonon scattering sites disposed in a random fashion in the surface, bulk, or edge of said phononic nanowires.

The phononic layer comprises phononic structure comprising, without limitation, holes, vias, pillars, surface dots, a field of nanowires, plugs, cavities, indentations, surface particulates, roughened edges, implanted molecular species, porous structure, and molecular aggregates, the phononic structures disposed in a periodic or random format.

In some embodiments, the at least one of the phononic nanowires includes a thin film metal or material of increased electrical conductivity, providing increased electrical conductivity for said nanowire.

In an embodiment, at least one of the phononic nanowires comprises a layer of dielectric material further comprising a thin film providing electrical isolation between nanowire layers and/or control of nanowire thermal coefficient of expansion (CTE) and nanowire flexure.

In an embodiment, platforms and nanowires are disposed within a hermetic cavity, wherein the cavity is configured and processed to provide a vacuum environment or filled with a gas of low thermal conductivity. In a further embodiment, the hermetic cavity is maintained in a vacuum condition, wherein a thermally-activated getter increases the vacuum level within the hermetic cavity.

In embodiments, the TCPS is fabricated from one or more semiconductor (SOI) starting wafers.

The TCPS may comprise a minimum lateral dimension ranging from 250 nanometers to multi millimeters.

The phononic nanowires of the TCPS are formed with a thickness or diameter ranging from 10 nm to 1 um.

In embodiments, a second substrate with a Peltier couple can be formed from a portion of a larger substrate. In these embodiments, only the nanowires are released from the second substrate, and the nanowires are anchored on a first substrate. The second substrate is created by a diffused p+ n+ couple by diffusion into the second substrate.

In embodiments, a second cooled substrate is configured to cool a third substrate. The third substrate can have an area similar to or larger than the second substrate. In embodiments, a plurality of second substrates are configured to cool a much larger third substrate.

In embodiments, a third substrate without a Peltier couple is thermally-coupled with a cooled substrate of the TCPS wherein the third substrate comprises a discrete photonic detector including, without limitation, a photodiode, thermistor bolometer, pyroelectric sensor, superlattice detector, or thermopile radiometer.

In embodiments, a substrate comprised of complex semiconductor devices or circuits such as a focal plane array (FPA) imager or thermopile radiometer is electrically connected to the surrounding heatsink substrate at least partially through-semiconductor-via (TSV) connections.

In applications, a substrate is supported by additional nanowires for the purpose of providing additional shock immunity to the substrate.

In embodiments, a cooled substrate provides a refrigerated surface providing, without limitation, storage of a media of interest, cooling for a semiconductor IC, or cooling of a chemical reaction.

In embodiments, the TCPS provides a cooler for a hyperspectral imaging system monitoring or detecting a remote source of photonic radiation.

In embodiments, the TCPS is a component within virtual reality eyeglasses (VRE) wherein an imager is cooled. The VRE is worn as headgear and in embodiments comprises both a cooled imager comprising TCPS structures and a micro-display.

In embodiments, a Seebeck temperature sensing function is time-shared with the Peltier cooling within the TCPS under external circuit control. External circuits enable the Seebeck sensor function within a few microseconds after disabling Peltier cooling. The thermoelectric signal during the Seebeck sensing interval provides an accurate measure of temperature for a cooled platform within the TCPS. The time required for the Seebeck sensing must be much less than the thermal time constant of the TCPS Peltier cooling structure.

The Seebeck signal is sensitive to heat absorbed continuously into a cooled platform of the TCPS if the cooled platform within the TCPS is exposed to a remote source of photonic radiation. In this application, the Seebeck signal irradiated from a remote scene is provided from each pixel of a cooled thermopile or cooled imaging array.

### BRIEF DESCRIPTION OF THE FIGURES

FIGS. 1A and 1B depict plan views of phononic nanowires.

FIGS. 2A, 2B and 2C depict cross-sectional views of phononic nanowires.

FIGS. 3A-3B depict cross-sectional views of a platform comprising a thermoelectric couple supported by phononic nanowires.

FIG. 3C depicts an isometric view of a platform elevated above a surrounding substrate by phononic nanowires.

FIG. 3D depicts a cross-sectional view of a platform on a surrounding substrate with nanowires elevated above the surrounding substrate.

FIGS. 4A, 4B depict cross-sectional views wherein a phononic structured nanowire supports a cooled substrate above a surrounding heatsink substrate providing increased rigidity.

FIG. 5 depicts a plan view wherein multiple stages of thermoelectric cooled platforms are powered from electrical connection into the first substrate.

FIGS. 6A-6B depict cross-sectional views of separate 2-stage thermoelectric coolers, each formed from a single starting semiconductor wafer.

FIG. 7A depicts a plan view of a first cooled substrate suspended by two nanowires wherein two additional nanowires are elevated upward from the first cooled substrate.

FIG. 7B depicts a cross-sectional view of a 2-stage thermoelectric cooler wherein the first stage is comprised of the FIG. 7A structure, and nanowires from the FIG. 7A structure extend upward to provide electrical and thermal contact with the cascaded lowest temperature substrate. A thermoelectric couple is disposed in the lowest temperature substrate.

FIG. 8 depicts 2-stage cooler wherein a second Peltier couple is disposed within a second cooled platform. Power for the second Peltier couple is supplied from a first platform such as depicted in FIG. 7A.

FIG. 9 depicts a cooling system comprising a plurality of TCPS structures wherein a top platform having extended area is cooled. Circuits disposed on the top platform are electrically connected to the surrounding heatsink substrate via TSV interposers. Additional nanowires provide increased mechanical support for the top platform.

### DETAILED DESCRIPTION

Definitions: The following terms are explicitly defined for use in this disclosure and the appended claims:
“comprising” means at least partially formed of.
“Peltier thermoelectric device” means a semiconductor heat pump, wherein a substrate comprising a thermocouple junction is cooled with power supplied from an external electric power source.
“thermocouple” or “couple” as used in this disclosure means only the lower temperature ohmic junction within a Peltier thermoelectric device. This ohmic couple is disposed within a cooled platform.
“package” means an encapsulation containing one or more of the TCPS structures. In embodiments, the package includes a hermetic seal around the TCPS contained within. The package includes electrical connections to external circuits.
“phononic crystal (PnC)” means a metamaterial structure comprised of periodically disposed nanostructure elements for reducing the transport of heat conducting phonons within nanowires.
“photonic detector” means a device sensitive to incident radiation within the range UV to mm wavelengths.
“superlattice detector” means photon sensor comprising a heterostructured photodiode or phototransistor with epitaxial layers of different semiconductors.
“nm, μm, mm” means units of nanometer, micrometer, and millimeter, respectively.
“ROIC” means an external circuit generally connected to the TCPS through the surrounding heatsink substrate.

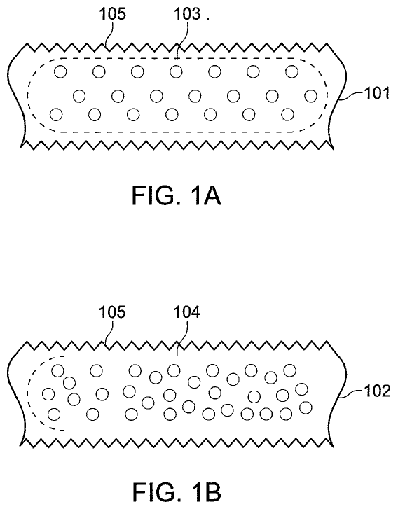

FIG. 1A depicts the topside plan view of the phononic layer of a nanowire embodiment. Nanowire 101 with structural elements 103 phononic crystal which reduces thermal transport for phonons within a limited acoustic bandwidth along the length of the nanowire. Phononic crystal is considered to be a resonant structure. The phononic crystal is formed of structures in the phononic nanowire disposed in an orderly fashion. Phononic crystal often comprises a “holey” structure in a flat nanowire, but phononic crystal may also be implemented with surface bumps, dimples, etc. The phononic nanowire surface structure 105 depicts a rough edge or surface of the nanowire which also limits the transport of phonons in the nanowire.

FIG. 1B depicts a random array of structural “holey” scattering elements 104 within the body of a phononic nanowire 102 wherein thermal transport along the nanowire length is reduced. Random scattering structure for reducing thermal conductivity is considered to be nonresonant structure. Edge scattering of phonons reducing thermal conductivity along the length of a phononic nanowire becomes more significant as the ratio of edge surface area to bulk volume increases for a nanowire.

In embodiments, phononic nanowire structural elements for reducing thermal conductivity comprises, without limitation, holes, vias, surface pillars, surface dots, plugs, cavities, indentations, surface particulates, roughened edges, implanted molecular species, and molecular aggregates, wherein the structural elements are disposed in a periodic or random format.

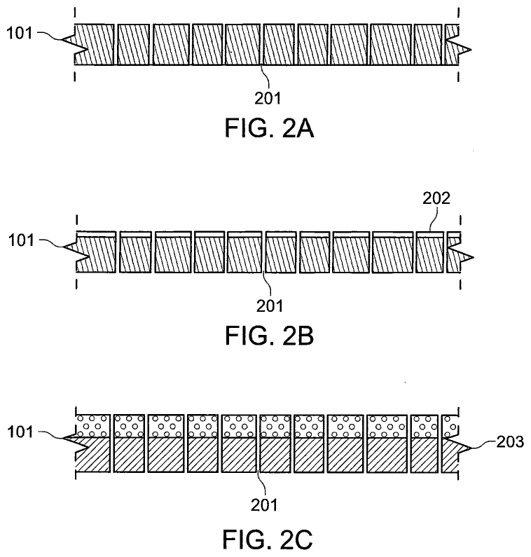

FIGS. 2A-2C depict the cross-sectional view of phononic nanowire 101 wherein the phononic first layer 101 includes phononic crystal having holes 201 penetrating through the thickness of the nanowire. The phononic layer 101 may comprise any semiconductor with significant electrical conductivity for powering the Peltier thermoelectric devices and significant mechanical strength often required to support a micro-platform. Thickness of the first layer phononic nanowire 101 ranges from 10 nm to 1 um.

FIG. 2B depicts a nanowire with a thin film metal, semiconductor, or dielectric layer 202 providing an increase in overall electrical conductivity or static positioning stress within the phononic nanowire.

FIG. 2C depicts a nanowire having a thin film dielectric layer 203. In embodiments, at least one nanowire includes a thin film dielectric comprising, without limitation, silicon dioxide, silicon nitride, magnesium fluoride, hafnium oxide, silicon oxynitride, aluminum oxide, PMMA, SU-8, XR-1541 providing electrical isolation between nanowire layers and/or control of mechanical stress.

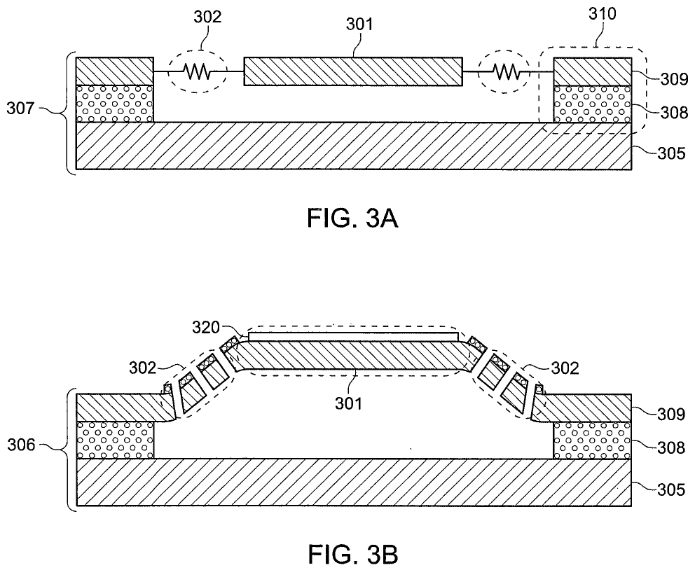

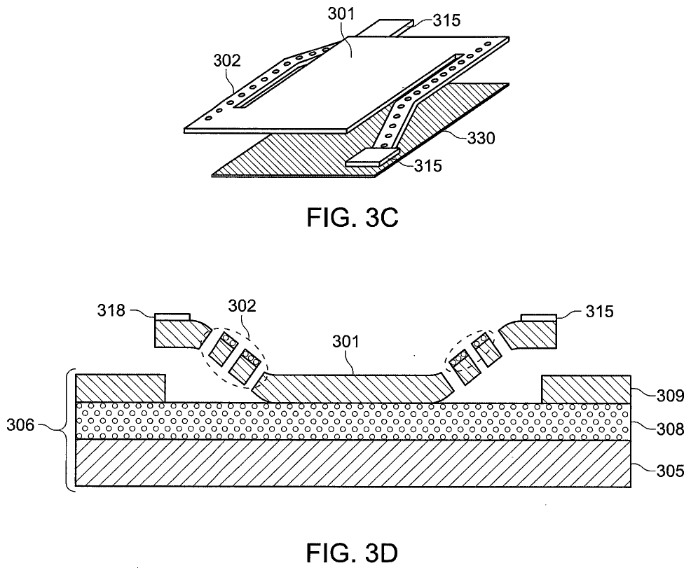

FIG. 3A and 3B depict a cross-sectional view of a substrate 301 supported by phononic nanowires 302. The nanowires are anchored on a surrounding substrate 307 comprising a semiconductor active layer 309, a dielectric insulating Box layer 308, and an underlying portion 305 within surrounding substrate 307. Substrate 301 is shown as having the same thickness as the semiconductor layer 309 wherein both the substrate and the nanowires are formed from the active layer of a starting semiconductor wafer. In embodiments, the depicted structure may be formed from the same SOI starting wafer. In embodiments, the platform and phononic nanowires are released from substrate area 305 by a release etch step.

FIG. 3B depicts a cross-sectional view of a substrate 301 comprised of a Peltier junction within a semiconductor platform. In embodiments, the platform 301 comprises a bonding film 320 facilitating thermal and/or electrical connection to an adjacent, touching structure. In this embodiment, the nanowires 302 comprise a semiconductor phononic layer and a covering dielectric film. The covering film is a dielectric having a different thermal coefficient of expansion (TCE) compared with the phononic nanowire layer creating internal stress to shape the nanowire to increase separation between platform 301 and substrate 305. This increased separation is required for some embodiments wherein the nanowires 302 are tethered onto separate substrates.

FIG. 3C depicts an isometric view of the FIG. 3B embodiment wherein platform 301 is raised above a platform 330. Platform 301 is supported from surrounding substrate 330 with phononic nanowires 302. Nanowires 302 are tethered onto substrate 330 through bonding pads 315. In FIG. 3C platform 301 is cooled by a Peltier thermocouple disposed within and powered through nanowires 302.

FIG. 3D depicts a cross-section of a substrate 301 bonded to dielectric 308 and semiconductor 305 layers of a thermoelectric structure. Phononic nanowires 302 are designed to extend increase separation between an end 315, 318 of each nanowire 302. A Peltier thermocouple junction is disposed within platform 301 and powered through nanowires 302. In FIG. 3D, platform 301 is cooled to a temperature reduced from the temperature of another platform bonded to pads 315, 318.

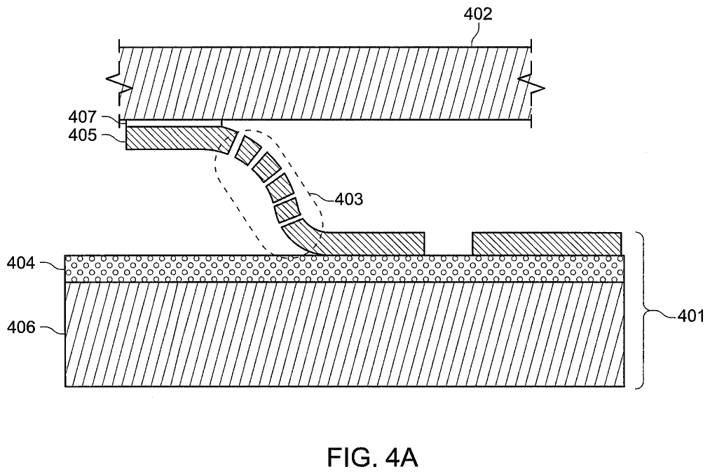

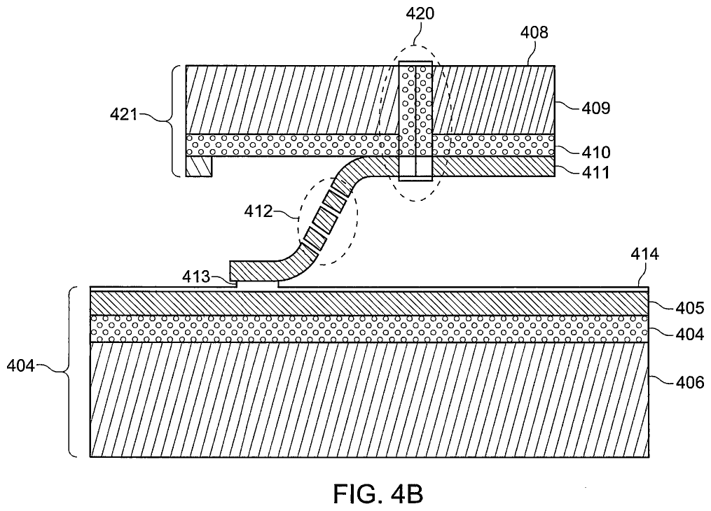

FIG. 4A depicts a cross-sectional view of a phononic nanowire 403 having a nonplanar shape supporting platform 421 over platform 404. Nanowire 403 is tethered at ending 413 to platform 404 through bonding film 413. This supporting nanowire 403 is tethered to platform 401 through dielectric film 404 and substrate 406.

FIG. 4B depicts a cross sectional view of a phononic nanowire 412 having a nonplanar shape physically connected between a surrounding heatsink substrate 404 and a through-semiconductor-via (TSV) 420 disposed in a cooled substrate 421. This embodiment of a phononic nanowire 412 provides both support rigidity for substrate 421 disposed above substrate 404 and an electrical connection. The electrical connection is provided from metal films 413, 414 on substrate 404, through the nanowires 412, and into a through-semiconductor-via (TSV) 420 created within substrate 421. In this embodiment structure, CMOS or other circuits are disposed in the upper surface of platform 409 and connection to readout and control circuits disposed on the surrounding substrate 404.

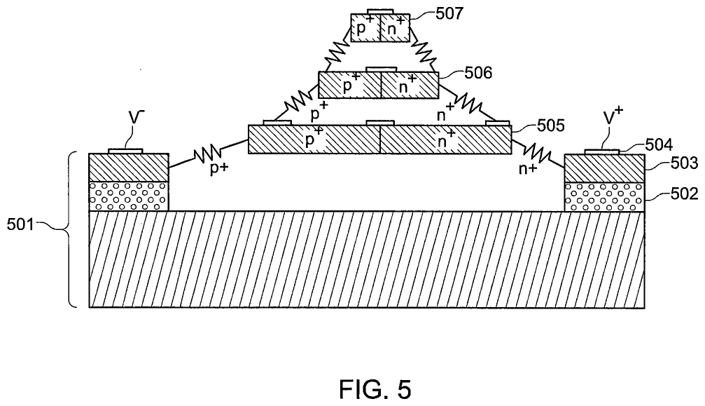

FIG. 5 depicts a cross-sectional view of a multi-stage TCPS comprising 3-stages of cooled substrates 505, 506, 507 suspended by nanowires above area 508 of substrate 501. The three cooled substrates are thermally- and electrically-connected in cascade, wherein substrate 507 is cooled to the lowest temperature compared with temperature of the heatsink substrate 501. External power is supplied to the 3-stage cooler embodiment through bonding pads 504. The heatsink substrate 501 comprises the underlying substrate area 508, dielectric film 502, and active semiconductor layer 503. The maximally cooled substrate 507 comprising a third Peltier couple receives power from thermally isolated substrate 506. Substrate 506 comprising a second Peltier couple receives power from thermally isolated substrate 505. Substrate 505 comprising a first Peltier couple receives power from the surrounding heatsink substrate 501.

### EXAMPLE 1 THERMOELECTRIC OOLER FORMED OF A SINGLE WAFER

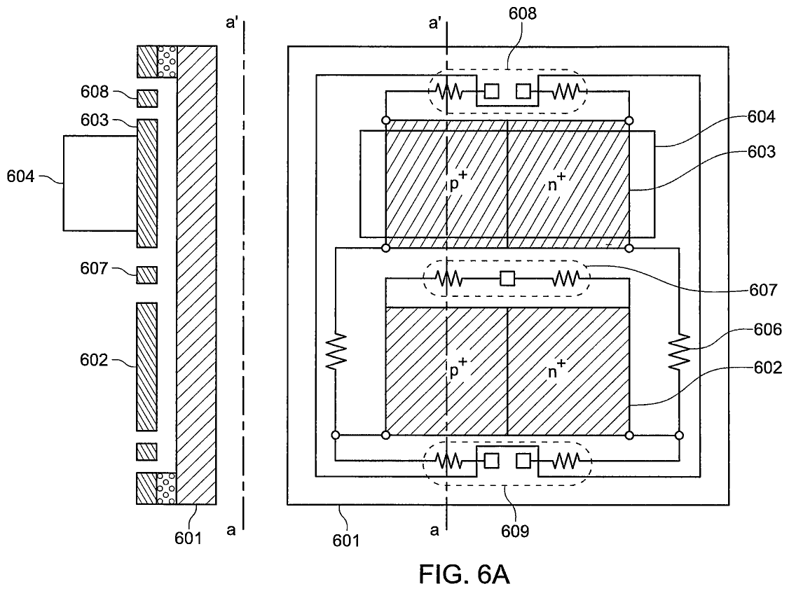

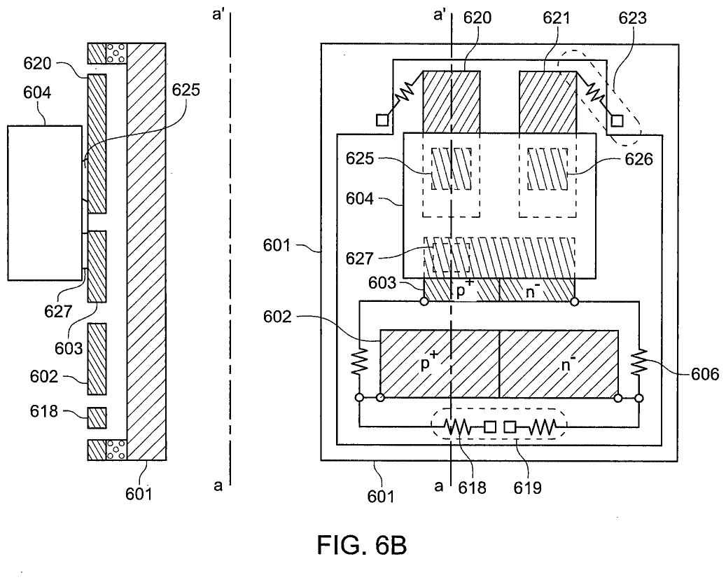

FIG. 6A depicts a plan view and a selected cross-section view of a two-stage TCPS integrated structure formed from a single semiconductor starting wafer. The first cooled platform 602 is suspended by phononic nanowires 609, 607 from surrounding heatsink substrate 601. The second cooled platform 603 receives power from the first cooled platform 602 through phononic nanowires 606. The second cooled platform is extended to overlying and thermally-connected structure 604.

FIG. 6A depicts the TCPS formed from a single starting SOI wafer. A first cooled substrate 602 receives power and is suspended from the surrounding heatsink substrate 601 through phononic nanowires 607, 609. A second cooled substrate 603 is supported by additional nanowires 608 suspended from a first cooled platform 602. The second cooled platform 603 is thermally- and electrically-connected to the first substrate 602 with phononic nanowires 606. Cooled substrates 602, 603 each comprise a Peltier junction couple. The second cooled substrate of FIG. 6A is supported additionally by phononic nanowires 608 providing physical support and incremental electrical power into the cooled substrate 602.

A media of interest 604 for cooling is thermally-connected or disposed on the second cooled substrate 603. Cooled substrates 602, 603 and supporting nanowires 607, 608, 609 are released with hot vapor HF from the underlying area within surrounding heatsink substrate 601 with a process step after structural areas for the cooled substrates and nanowires are patterned in detail. FIG. 6A in embodiments is formed from a semiconductor SOI starting wafer.

FIG. 6B depicts an embodiment wherein an ohmic connection is provided between the media of interest 604 and the surrounding substrate 601 through nanowires 623. In this embodiment the media of interest 604 may comprise an integrated circuit device such as a photonic detector. Said ohmic connection is enabled through separate signal bonding pads 625, 626 providing an electrical connection between the device 604, through semiconductor layer 620, and nanowires 623 tethered to the surrounding heatsink substrate 601. In embodiments, the ohmic connection connects a cooled device 604 with external ROIC circuits.

### EXAMPLE 2: THERMOELECTRIC COOLER FORMED FROM MULTIPLE STARTING WAFERS

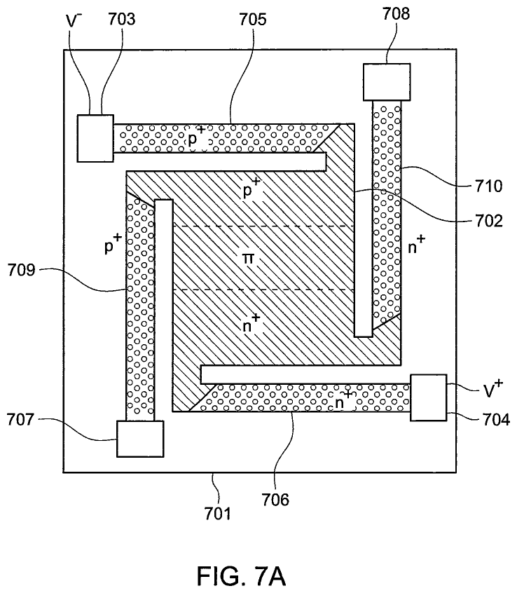

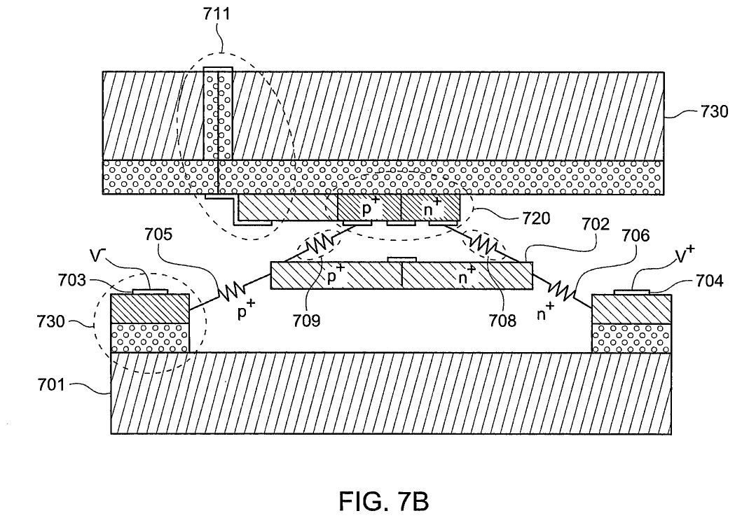

FIG. 7A depicts a plan view of the first stage of a TCPS that includes a first cooled substrate 702 and connecting nanowires. The first cooled substrate 702 comprises a Peltier couple. The first cooled substrate 702 is suspended with nanowires 705, 706 anchored to bonding pads 703, 704, wherein the bonding pads are disposed on surrounding heatsink substrate 701. Nanowires 709, 710 provide a thermal and electrical connection through pads 707,708 to the second cooled substrate 720 of FIG. 7B.

FIG. 7B depicts a cross-sectional view of the FIG. 7A structure with a second cooled platform 720 added. The second substrate 720 is bonded to pads 707, 708 of the first cooled stage. Associated nanowires 707, 708 are processed to curve upward to facilitate aligned wafer bonding of substrate 720 over substrate 701. The second cooled substrate 720 comprises a Peltier couple. Phononic nanowires 707,708 are structured to bend significantly upward by adding a dielectric layer to the phononic layer of these two nanowires increasing bending stress during the fabrication process. In a preferred embodiment, the structures of FIG. 7B are fabricated from two separate SOI starting wafers wherein the second cooled substrate 720 is the active layer within the layered SOI structure 730.

In FIG. 7B, the larger platform 730 from the SOI wafer comprising a second substrate 720 comprising a Peltier couple is processed to include a TSV via 711 connected with structured wiring patterned on active layer 731.

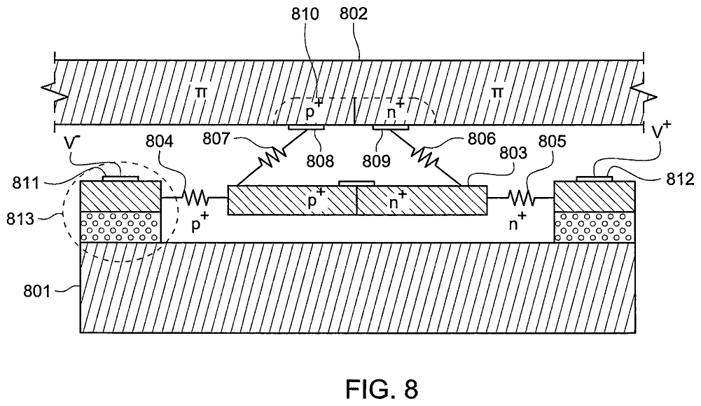

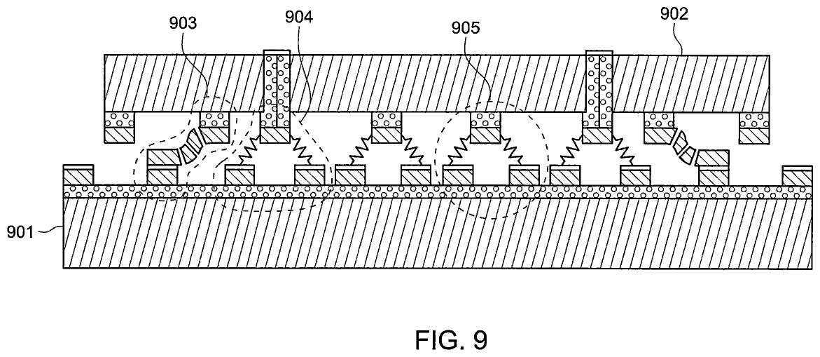

FIG. 8 depicts a cross sectional view of a 2-stage TCPS cooler wherein a Peltier couple 810 is diffused into a second starting wafer 802 to provide a cooled second substrate 802. The first cooled substrate in this embodiment is similar to the first cooled substrate depicted in FIG. 7A wherein nanowires 806, 807 are processed to bend upward from the first cooled substrate 803. Nanowires 804, 805 support the first cooled platform 803. The first cooled substrate and its nanowires are formed from an SOI starting wafer comprised of active layer 813, dielectric Box layer 813, and surrounding heatsink substrate 801. External power for the TCPS is provided through terminals 811, 812.

FIG. 9 depicts a cross-sectional view of a 2-stage TCPS cooler comprising several functional structures, each providing significant thermal isolation between a surrounding heatsink substrate 901 and platform 902 cooled by TCPS structure 905. Substrate 902 is formed from a starting SOI wafer. The surrounding heatsink substrate 901 may also be formed of a starting SOI wafer, although the intermediate structures 905,904,903 may be formed from additional MEMS semiconductor structure. The intermediate structures include muti-stage coolers 905, interconnects comprising TSV structure 904, and phononic nanowires 903 specifically structured to provide rigidity for the larger substrate 902.

A plurality of phononic structures are connected to substrate 902 providing cooling, ohmic connection, and rigid support for the larger area substrate. A plurality of cooling platform structures 905 cools the larger substrate 902. A plurality of ohmic connection platform structures 905 connect into the through-semiconductor-vias (TSV) providing electric connection to integrated circuits disposed on the upper surface of cooled substrate 902. Nanowire support structures disposed between substrates 901 and 902 provide rigidity for substrate 902. Structures 903, 904,905 each physically connect between the cooled substrate and the heatsink substrate.

One application embodiment for FIG. 9 is an imaging system for a remote scene imaged onto the surface of substrate 902. Substrate 902 may comprise a photonic focal plane array for imaging. In another embodiment, imaging array is disposed within wearable virtual reality eyeglasses (VRE).

### EXAMPLE 3: TIME-SHARED COOLING/SENSING EMBODIMENT

In embodiments based on structures of FIGS. 6,7,8,9 the second cooled thermoelectric structure may be operated to provide Peltier cooling during a first time internal, wherein external circuits provide power for the Peltier cooling. A Seebeck sensing function is enabled during a second time interval immediately following the first time interval. External circuits providing power are disconnected and replaced by a voltage sensor which is sensitive to the temperature of the second cooled platform providing a means of sensing a Seebeck voltage from the thermocouples disposed on the second platform.

In this embodiment, the platform at the lowest temperature may comprise a thermal imager wherein the sensed Seebeck voltage is proportional to the absorbed power from incident radiation as sourced with external optics with radiation from an external scene. In this embodiment, the incident radiation heating the second platform requires a reference sensing level. This reference sensing level is obtained by synchronously chopping the incident radiation beam, or by providing a separate Peltier/Seebeck structure that is not exposed to the incident radiation of interest.

It is to be understood that although the disclosure teaches many examples of embodiments in accordance with the present teachings, many additional variations of the invention can easily be devised by those skilled in the art after reading this disclosure. As a consequence, the scope of the present invention is to be determined by the following claims.

What is claimed is:

1. A multi-stage thermoelectric cooler with phononic structure (TCPS) comprising a plurality of cooled substrates, wherein each cooled substrate comprises one or more Peltier thermoelectric couples, wherein:
one or more first cooled substrates are at least partially suspended from a heatsink substrate and receive power from the heatsink substrate through phononic nanowires;
one or more additional cooled substrates are each at least partially suspended from and powered from a cooled substrate maintained at a higher temperature, wherein the one or more additional cooled substrates each receive power from a cooled substrate maintained at a higher temperature;
the phononic nanowires comprise a semiconductor phononic layer structured with resonant and/or nonresonant elements providing a reduced thermal conductivity for each phononic nanowire;
the phononic layer increases the ratio of electrical conductivity to thermal conductivity along the length of each phononic nanowire, and
the cooled substrates are connected in a thermal cascade, wherein each cooled substrate is cooled to a temperature lower than the substrate supplying power, thereby providing a TCPS wherein one substrate within the cascade is cooled to a minimum temperature.

2. The TCPS of claim 1 wherein a second cooled substrate is suspended by phononic nanowires from one or more first cooled substrates, and the first cooled substrates provide power to the Peltier thermocouples disposed in the second cooled substrate.

3. The TCPS of claim 1 adapted with ancillary phononic nanowires physically supporting a platform without supplying power to said platform, thereby providing mechanically rigid support or positioning stress.

4. The TCPS of claim 1 comprising a cooled platform maintained at a minimum temperature, thermally connected to the low temperature platforms of a plurality of individual TCPS coolers.

5. The TCPS of claim 1 wherein the one or more cooled platforms comprise, or are thermally-connected to, a discrete photonic detector or array of sensors including, without limitation, a thermopile, photodiode, superlattice detector, thermistor bolometer, or pyroelectric sensor.

6. The TCPS of claim 5 wherein the photonic detector or array of sensors comprises a cooled imager disposed within virtual reality eyeglasses (VRE).

7. The TCPS of claim 5 wherein a CMOS readout integrated circuit (ROIC) is partially disposed in a cooled platform or in the surrounding heatsink substrate.

8. The TCPS of claim 5 adapted, wherein some phononic nanowires are positioned to provide an ohmic circuit connection between circuit elements disposed on platforms that do not comprise Peltier thermocouples.

9. The TCPS of claim 5 providing a time-shared cooling/sensing function wherein platform Peltier cooling and Seebeck temperature sensing functions are enabled during adjacent time intervals.

10. The TCPS of claim 1 configured to provide a refrigerated environment for short and long term storage of a media of interest, the media of interest comprising without limitation, a chemical material, or a semiconductor device.

11. The TCPS of claim 1 wherein the phononic layer of nanowires comprises a crystalline or polycrystalline semiconductor, wherein structural elements within the phononic layer are physically separated by less than the mean-free-path (mfp) of at least some heat conducting phonons.

12. The TCPS of claim 1 wherein the phononic layer comprises one or more of a semiconductor material selected from the group, without limitation, silicon, silicon germanium, silicon carbide, gallium nitride, organic semiconductor, and semiconductor compounds of antimony, bismuth, cobalt, lanthanum, lead, selenium, sulfur, tellurium, vanadium.

13. The TCPS of claim 1 wherein the phononic layer of the nanowires comprises phononic crystal (PnC) having a phononic bandgap, wherein structural sites are arranged in an orderly fashion, and the phononic crystal reduces thermal transport of phonons.

14. The TCPS of claim 1 wherein the phononic layer of at least some phononic nanowires includes nonresonant scattering structure having phonon scattering sites disposed in a random fashion in the surface, bulk, or edge of said phononic nanowires.

15. The TCPS of claim 1 wherein the phononic layer comprises phononic structure, without limitation, holes, vias, pillars, surface dots, a field of nanowires, plugs, cavities, indentations, surface particulates, roughened edges, implanted molecular species, porous structure, and molecular aggregates, the phononic structures disposed in a periodic or random format.

16. The TCPS of claim 1 wherein at least one of the phononic nanowires includes a thin film material of increased electrical conductivity, providing increased electrical conductivity for said nanowire.

17. The TCPS of claim 1 wherein at least one of the phononic nanowires comprises a layer of dielectric material providing electrical isolation between nanowire layers and/or control of nanowire thermal coefficient of expansion and nanowire flexure.

18. The TCPS of claim 1 wherein platforms and nanowires are disposed within a hermetic cavity, the cavity configured to provide a vacuum environment or filled with a gas of low thermal conductivity.

19. The TCPS of claim 18 wherein a thermally-activated getter increases the vacuum level within the hermetic cavity.

20. The TCPS of claim 1 wherein the cooled platforms comprise a minimum lateral dimension ranging from 250 nanometers to multi-millimeters.

21. The TCPS of claim 1 wherein the phononic nanowires are formed with a thickness or diameter ranging from 10 nanometers to 1 micrometer.
